(19) United States
(12) Patent Application Publication
(10) Pub. No.: US 2022/0184768 A1
(43) Pub. Date: Jun. 16, 2022

(54) EDGE TRIMMING METHOD

(71) Applicant: DISCO CORPORATION, Tokyo (JP)

(72) Inventors: Takashi OKAMURA, Tokyo (JP); Shigenori HARADA, Tokyo (JP)

(21) Appl. No.: 17/455,062

(22) Filed: Nov. 16, 2021

(30) Foreign Application Priority Data
Dec. 11, 2020 (JP) 2020-205661

(51) Int. Cl. B24B 9/06; B24B 37/30; B28D 5/00; B28D 5/02

(52) U.S. Cl. CPC B24B 9/065; B28D 5/026; B28D 5/0082; B24B 37/30

(57) ABSTRACT

An edge trimming method for cutting an outer peripheral portion of a workpiece having a chamfered part on the outer peripheral portion. The method includes a cut in step of relatively moving a rotating cutting blade and a chuck table to cause the blade to cut into the outer peripheral portion, a cutting step of, after the cut in step, rotating the chuck table and causing the outer peripheral portion to be cut, to form an annular step, and a moving step of, after the cutting step, moving the blade in a direction of its axis of rotation to form another annular step adjacent to the first-mentioned annular step. The cut in, cutting, and moving steps are repeated in this order, and a stepped oblique region is formed on the outer peripheral portion, with a thickness increasing from an outermost peripheral edge toward an inner side of the workpiece.

### BACKGROUND OF THE INVENTION

### Field of the Invention

The present invention relates to an edge trimming method for cutting an outer peripheral portion of a workpiece having a chamfered part on the outer peripheral portion.

### Description of the Related Art

In a manufacturing process of semiconductor device chips, a disc-shaped semiconductor wafer (in other words, a workpiece) formed of a semiconductor material such as silicon is generally ground evenly at a back surface of the workpiece, the back surface being located on a side opposite to a front surface in which devices are formed, to thin the workpiece. In general, however, chamfered parts (also called “bevel parts”) are formed on respective outer peripheral portions on the sides of the front and back surfaces of the workpiece. What is generally called a knife edge (also called a “sharp edge”) is thus formed on the outer peripheral portion on the side of the front surface when the workpiece is ground at the back surface and is thinned to a thickness, for example, equal to or smaller than a half. The workpiece so thinned is liable to breakage from the knife edge as a starting point.

To avoid such breakage, there have hence been proposed methods that, before grinding a workpiece, perform edge trimming to remove a chamfered part on the side of a front surface of the workpiece and, after this edge trimming, grind the workpiece at a back surface (see, for example, Japanese Patent Laid-open No. 2000-173961). If the workpiece is ground at the back surface after the edge trimming, however, a relatively large arcuate region (for example, of 5 cm or so) may chip off as an off-cut from the outer peripheral portion on the side of the back surface due to impact or the like of the grinding. Such a relatively large off-cut cannot be collected by a collecting system for ground debris, which is generally arranged in a grinding apparatus. It is therefore necessary for a worker to collect such an off-cut by hand whenever it is generated.

### SUMMARY OF THE INVENTION

With such a problem in view, the present invention is directed to reducing a volume of an off-cut that is to be generated during grinding.

In accordance with a first aspect of the present invention, there is provided an edge trimming method for cutting an outer peripheral portion of a workpiece having a chamfered part on the outer peripheral portion. The edge trimming method includes a holding step of holding the workpiece on a holding surface of a chuck table, a cut in step of, after the holding step, relatively moving a rotating cutting blade and the chuck table to cause the cutting blade to cut into the outer peripheral portion of the workpiece, a cutting step of, after the cut in step, rotating the chuck table and causing the outer peripheral portion of the workpiece to be cut, to form an annular step, and a moving step of, after the cutting step, moving the cutting blade in a direction of an axis of rotation of the cutting blade to form another annular step adjacent to the first-mentioned annular step. The cut in step, the cutting step, and the moving step are repeated in this order, and a stepped oblique region is formed on the outer peripheral portion, with a thickness increasing from an outermost peripheral edge toward an inner side of the workpiece.

In accordance with a second aspect of the present invention, there is provided an edge trimming method for cutting an outer peripheral portion of a workpiece having a chamfered part on the outer peripheral portion. The edge trimming method includes a holding step of holding the workpiece on a holding surface of a chuck table and a processing step of, after the holding step, concurrently performing relatively moving a rotating cutting blade and the chuck table to cause the cutting blade to cut into the outer peripheral portion of the workpiece, rotating the chuck table, and moving the cutting blade in a direction of an axis of rotation of the cutting blade. In the processing step, a stepped oblique region is formed on the outer peripheral portion, with a thickness increasing from an outermost peripheral edge toward an inner side of the workpiece and also with a bottom surface helically formed over a plurality of steps when the oblique region is viewed in plan.

In the edge trimming method according to each of the first and second aspects of the present invention, there is formed on the outer peripheral portion the stepped oblique region with the thickness increasing from the outermost peripheral edge toward the inner side of the workpiece. Owing to the stepped oblique region, an off-cut is rarely generated in the first place, for example, when the workpiece is ground at the back surface after removal of the chamfered part on the side of the front surface. Even if the off-cut is generated, the off-cut can be reduced in volume and arcuate length compared with an arcuate off-cut that would be generated if a workpiece with only one step formed by the conventional edge trimming method is ground at a back surface thereof. Even if such an off-cut is generated, there is accordingly a high possibility that the off-cut can be collected by a grinding debris collecting system generally arranged in a grinding apparatus, thereby enabling a reduction in a frequency at which a worker collects off-cuts by hand.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of a workpiece and a chuck table of a cutting apparatus, and illustrates a holding step in an edge trimming method according to an embodiment of a first aspect (the embodiment may hereinafter simply be referred to as the “first embodiment”) of the present invention;

FIG. 2A is a partially cross-sectional, fragmentary side view of the workpiece and the cutting apparatus, and illustrates a cut in step of the edge trimming method;

FIG. 2B is a fragmentary perspective view of the workpiece and the cutting apparatus, and illustrates the cut in step of FIG. 2A;

FIG. 3A is a partially cross-sectional, fragmentary side view of the workpiece and the cutting apparatus, and illustrates a cutting step in the edge trimming method;

FIG. 3B is a fragmentary perspective view of the workpiece and the cutting apparatus, and illustrates the cutting step of FIG. 3A;

FIG. 4A is a partially cross-sectional, fragmentary side view of the workpiece and the cutting apparatus, and illustrates a moving step in the edge trimming method;

FIG. 4B is an enlarged cross-sectional view of an outer peripheral portion of the workpiece in the moving step of FIG. 4A;

FIG. 5A is an enlarged cross-sectional view of the outer peripheral portion of the workpiece, and illustrates a second cut in step in the edge trimming method;

FIG. 5B is an enlarged cross-sectional view of the outer peripheral portion obtained after a second cutting step in the edge trimming method;

FIG. 6A is an enlarged cross-sectional view of the outer peripheral portion of the workpiece obtained after edge trimming by the edge trimming method;

FIG. 6B is a partially cross-sectional view of the workpiece in its entirety and a portion of the chuck table, and illustrates the workpiece obtained after the edge trimming of FIG. 6A;

FIG. 7 is a flow diagram illustrating the edge trimming method according to the first embodiment of the present invention;

FIG. 8A is a view illustrating how the workpiece is ground at a back surface thereof after formation of an oblique region by the edge trimming method of FIG. 7;

FIG. 8B is an enlarged cross-sectional view of a region surrounded by an ellipse in FIG. 8A;

FIG. 9A is a view illustrating how a workpiece, which has only one step formed by an edge trimming method according to a comparative example of the first embodiment, is ground at a back surface of the workpiece;

FIG. 9B is an enlarged cross-sectional view of a region surrounded by an ellipse in FIG. 9A;

FIG. 10A is an enlarged cross-sectional view of an outer peripheral portion of a workpiece, and illustrates a first cut in step in an edge trimming method according to a modification of the first embodiment of the present invention;

FIG. 10B is an enlarged cross-sectional view of the outer peripheral portion of FIG. 10A, and illustrates an order in which a plurality of steps are formed in the edge trimming method of FIG. 10A;

FIG. 11 is a flow diagram of an edge trimming method according to an embodiment of a second aspect (the embodiment may hereinafter simply be referred to as the “second embodiment”) of the present invention;

FIG. 12 is a top plan view of a workpiece obtained after a processing step in the edge trimming method of FIG. 11;

FIG. 13A is an enlarged, partially cross-sectional view of an outer peripheral portion of a workpiece and the portion of the chuck table, and illustrates an edge trimming method according to a modification of the first embodiment, its modification, or the second embodiment (the modification may hereinafter simply be referred to as the “third embodiment”), in which a cutting blade having a blade thickness greater than a width of an outer peripheral surplus region is used; and

FIG. 13B is an enlarged, partially cross-sectional view of an outer peripheral portion of a workpiece and the portion of the chuck table, and illustrates an edge trimming method according to another modification of the first embodiment, its modification, or the second embodiment (the modification may hereinafter simply be referred to as the “fourth embodiment”), in which a cutting blade having a blade thickness smaller than a width of an outer peripheral surplus region is used.

### DETAILED DESCRIPTION OF THE PREFERRED EMBODIMENTS

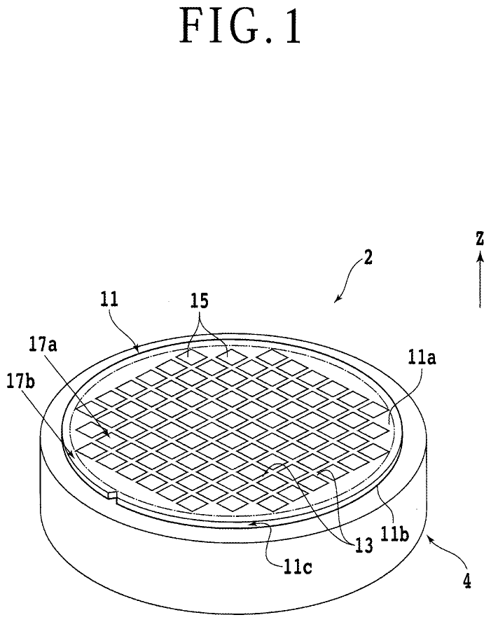

With reference to the attached drawings, an embodiment of a first aspect (which may hereinafter simply be referred to as the “first embodiment”) of the present invention, a comparative example and a modification of the first embodiment, an embodiment of a second aspect (which may hereinafter simply be referred to as the “second embodiment”) of the present invention, and two modifications (which may hereinafter simply be referred to as “the third embodiment” and “the fourth embodiment”) of the first embodiment, the modification of the first embodiment, or the second embodiment will hereinafter be described in detail. Referring first to FIG. 1, a description will be made with regard to a workpiece 11 to which edge trimming is to be applied. FIG. 1 is a perspective view of the workpiece 11 and a disc-shaped chuck table 4 of a cutting apparatus 2, and illustrates a holding step in an edge trimming method according to the first embodiment of the present invention. The workpiece 11 is, for example, a disc-shaped wafer formed of a semiconductor material such as silicon. The workpiece 11 has, for example, a diameter of approximately 300 mm and a predetermined thickness of 100 μm or greater but 800 μm or smaller. The workpiece 11 is divided at a front surface 11a thereof into a plurality of regions by a plurality of intersecting scribe lines (streets) 13.

In the respective regions, a plurality of devices 15 such as integrated circuits (ICs) or large scale integration (LSI) circuits are formed. The devices 15 are arranged in a circular device region 17a. Outside the device region 17a, an annular outer surplus region 17b having no device 15 is present such that the annular outer surplus region 17b surrounds a periphery of the device region 17a. For the sake of convenience, a boundary line between the device region 17a and the outer surplus region 17b is indicated by an alternate long and short dash line in FIG. 1.

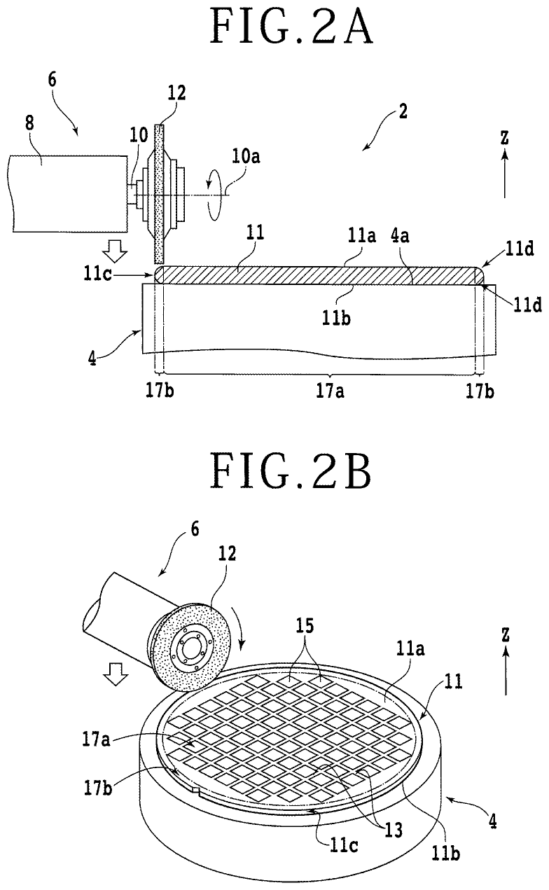

On each of an outer peripheral portion 11c on a side of the front surface 11a and an outer peripheral portion 11c on a side of a back surface lib, a chamfered part (also called a “bevel part”) 11d (see FIG. 2A) is formed extending over the entire periphery of the outer peripheral portion 11c. When edge trimming is to be applied to the workpiece 11, the cutting apparatus 2 is used. As illustrated in FIG. 1, the cutting apparatus 2 has the chuck table 4. The chuck table 4 has a disc-shaped frame member formed of non-porous resin.

A disc-shaped recessed portion (not illustrated) is formed in an upper portion of the frame member, and a disc-shaped porous plate formed of porous ceramics is fixed in the recessed portion. The porous plate has an upper surface, which is substantially flush with an upper surface of the frame member, and is disposed substantially in parallel to a horizontal plane (X-Y plane) that is substantially orthogonal with an up-down direction (Z-axis direction) of the cutting apparatus 2. To the upper surface of the porous plate, a negative pressure is transmitted from a suction source (not illustrated) such as an ejector via a flow path (not illustrated) arranged in the frame member. The upper surface of the porous plate and the upper surface of the frame member function as a holding surface 4a that sucks and holds the workpiece 11 (see FIG. 2A).

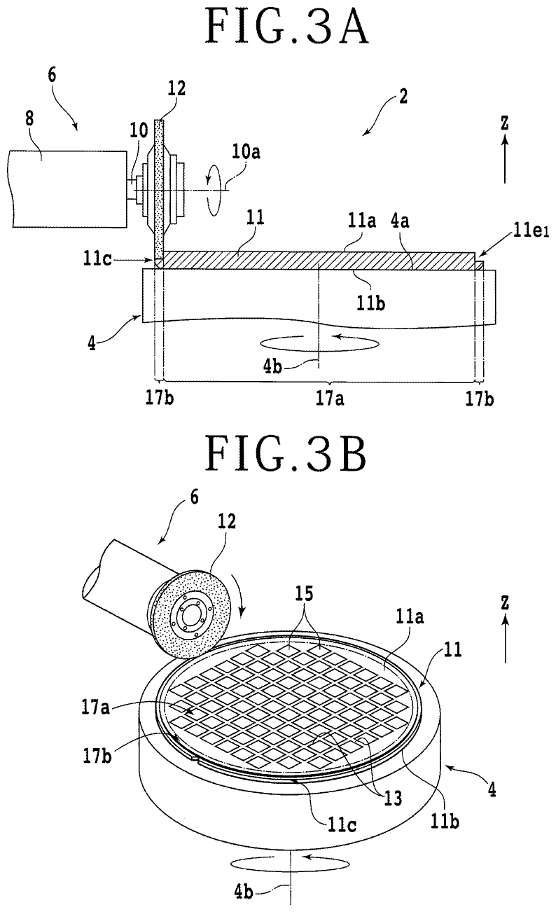

To a lower portion of the chuck table 4, an output shaft (not illustrated) of a first rotary drive source such as a motor is connected. When the first rotary drive source is operated, the chuck table 4 rotates in a predetermined direction about the output shaft as an axis 4b of rotation (see FIG. 3A). Below the first rotary drive source, an X-axis moving mechanism of the ball screw type (not illustrated) is disposed to move the chuck table 4 in the X-axis direction. Above the holding surface 4a, a cutting unit 6 (see FIG. 2A) is disposed.

With reference to FIG. 2A, a configuration of the cutting unit 6 will be described. FIG. 2A is a partially cross-sectional, fragmentary side view of the workpiece 11 and the cutting apparatus 2, and illustrates a cut in step of the edge trimming method. The cutting unit 6 has a substantially cylindrical spindle housing 8. To the spindle housing 8, a Z-axis moving mechanism of the ball screw type (not illustrated) is connected to move the cutting unit 6 up and down along the Z-axis direction. To the Z-axis moving mechanism, a Y-axis moving mechanism of the ball screw type (not illustrated) is connected to move the cutting unit 6 along the Y-axis direction. It is to be noted that the X-axis direction, the Y-axis direction, and the Z-axis direction are orthogonal with one another.

In the spindle housing 8, a portion of a cylindrical spindle 10, which is disposed substantially in parallel to the Y-axis direction, is rotatably accommodated. On an end portion (proximal end portion) of the spindle 10, a second rotary source such as a servo motor is disposed. On an opposite end portion (distal end portion) of the spindle 10, an annular cutting blade 12 is mounted. The cutting blade 12 used in this embodiment has substantially the same blade thickness as a width (for example, approximately 3 mm) of the outer surplus region 17b. In FIG. 2A, a cutting blade of the hubless type (also called the “washer type”), which includes a cutting blade alone and no annular hub, is illustrated as the cutting blade 12. Instead of such a hubless cutting blade, a cutting blade of the hub type, which has a hub and a cutting blade, may also be used as the cutting blade 12.

Referring next to FIGS. 1 through 8B, a description will be made about the edge trimming method of the first embodiment in which the outer peripheral portion 11c on the side of the front surface 11a is to be cut. As illustrated in FIG. 1, the workpiece 11 is first placed on the holding surface 4a such that the back surface 11b of the workpiece 11 is brought into contact with the holding surface 4a. Upon this placement, a center on the side of the front surface 11a and a center of the holding surface 4a are substantially brought into coincidence with each other in the direction of the X-Y plane. At this time, the workpiece 11 has a thickness direction substantially in parallel to the Z-axis direction. A negative pressure is next caused to act on the upper surface of the porous plate to hold the workpiece 11 under suction on the holding surface 4a (holding step S10).

After the holding step S10 illustrated in FIG. 1, the spindle 10 is rotated, and the cutting blade 12 is rotated about an axis 10a of rotation. However, the chuck table 4 is kept in a stationary state without rotation. Respective positions of the cutting unit 6 and the chuck table 4 are then adjusted such that an extension of the axis 10a of rotation of the spindle 10 intersects an extension of the axis 4b of rotation (see FIG. 3A) of the chuck table 4 and the cutting blade 12 is located right above the outer peripheral portion 11c.

By next relatively moving the cutting blade 12 and the chuck table 4, the cutting blade 12 cuts into the outer peripheral portion 11c on the side of the front surface 11a (cut in step S20). In this embodiment, the cutting blade 12 cuts into the outer peripheral portion 11c by what is generally called chopper cutting through a downward movement of the cutting unit 6 by the Z-axis moving mechanism. In the cut in step S20, the cutting blade 12 cuts into the outer peripheral portion 11c such that the cutting blade 12 intersects the front surface 11a at right angles. The cut in amount from the front surface 11a toward the back surface 11b is set, for example, equal to a predetermined depth that does not reach the back surface 11b (for example, from 100 μm to 200 μm).

FIG. 2B is a fragmentary perspective view of the workpiece 11 and the cutting apparatus 2, and illustrates the cut in step of FIG. 2A. It is to be noted that, in the cut in step S20, the cutting blade 12 may also cut into the outer peripheral portion 11c on the side of the front surface 11a by relatively moving the cutting unit 6 and the chuck table 4 in the X-axis direction instead of performing chopper cutting.

After the cut in step S20, the position of the cutting unit 6 is fixed while the cutting blade 12 is kept rotating. By rotating the chuck table 4 approximately one turn about the axis 4b of rotation in this state, an annular step 11e₁ (see FIG. 3A) is formed on the outer peripheral portion 11c on the side of the front surface 11a (cutting step S30). It is to be noted that, in the cutting step S30, the chuck table 4 is required to be rotated one turn or more and may be rotated 1.5 turns or 2 turns. Insofar as the chuck table 4 is rotated one turn or more, the annular step 11e₁ can be formed through partial cutting of the outer peripheral portion 11c on the side of the front surface 11a in a depth direction of the workpiece 11.

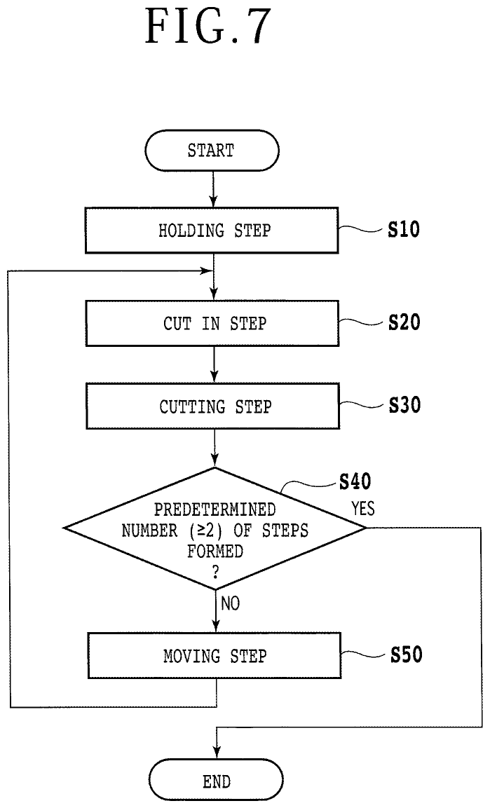

FIG. 3A is a partially cross-sectional, fragmentary side view of the workpiece 11 and the cutting apparatus 2, and illustrates a cutting step 30 in the edge trimming method, and FIG. 3B is a fragmentary perspective view of the workpiece 11 and the cutting apparatus 2, and illustrates the cutting step S30 of FIG. 3A. After the cutting step S30, it is determined whether or not the number of the step(s) so formed is a predetermined number or greater (determination step S40) (see FIG. 7). The determination step S40 is performed by a control unit (not illustrated), which controls operations of the cutting apparatus 2, on the basis of, for example, information regarding a moving operation of the cutting unit 6. The control unit includes a computer including, for example, a processor (processing unit) represented by a central processing unit (CPU), a main storage device such as a dynamic random access memory (DRAM), a static random access memory (SRAM), or a read only memory (ROM), and an auxiliary storage device such as a flash memory, a hard disk drive, or a solid-state drive. In the auxiliary storage device, software including predetermined programs is stored. Functions of the control unit are realized by operating the processing device or the like according to the software. However, instead of the control unit, a worker may make the determination.

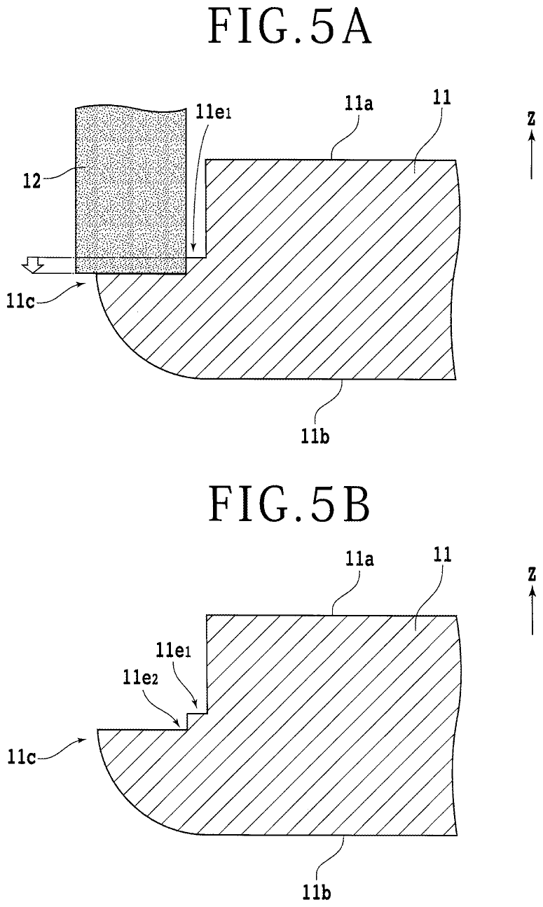

The number of steps is set at a predetermined number of 2 or greater (4 in this embodiment). As the four steps are to be formed in this embodiment (“NO” in S40), the method proceeds to a moving step S50. If the four steps have already been formed (“YES” in S40), however, the edge trimming is ended. In the moving step S50 right after the first cutting step S30, the chuck table 4, for example, is brought into a stationary state. To form another annular step 11e₂ (see FIG. 5B) adjacent to the step 11e₁ but outside the step 11e₁, the cutting blade 12 is moved to an outer side of the holding surface 4a. Described specifically, the Y-axis moving mechanism is used to move the cutting unit 6 by a minute distance (for example, 0.75 mm) to the outer side of the holding surface 4a along the direction of the axis 10a of rotation (in other words, the Y-axis direction).

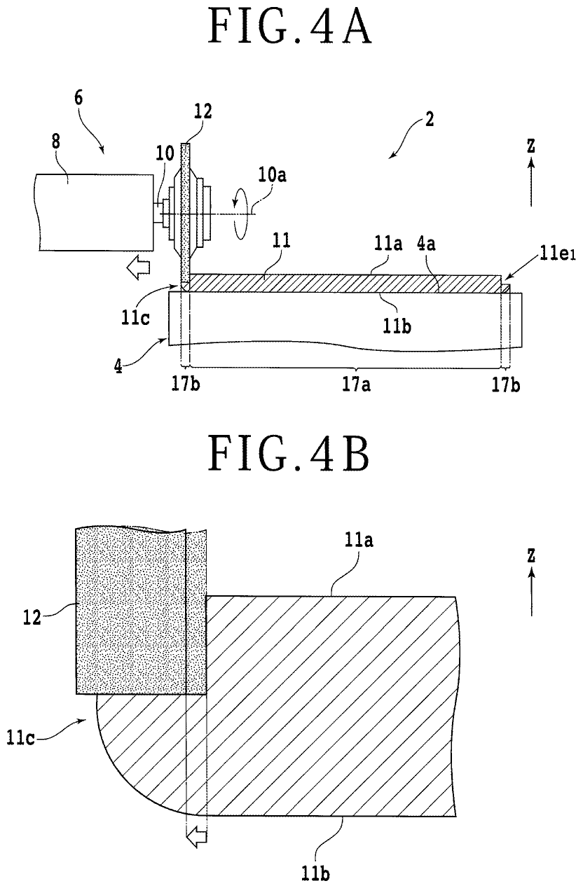

FIG. 4A is a partially cross-sectional, fragmentary side view of the workpiece 11 and the cutting apparatus 2, and illustrates the moving step S50 in the edge trimming method, and FIG. 4B is an enlarged cross-sectional view of the outer peripheral portion 11c of the workpiece 11 in the moving step S50 of FIG. 4A. In the moving step S50, the cutting blade 12 is moved, in association with the movement of the cutting unit 6, to the outer side of the holding surface 4a by the minute distance indicated by an arrow, as illustrated in FIG. 4B. It is to be noted that, in the moving step S50, the cutting blade 12 may also be moved to the outer side of the holding surface 4a with the chuck table 4 still kept rotating continuously from the cutting step S30. After the moving step S50, the method returns to the cut in step S20.

In a second cut in step S20, the rotating cutting blade 12 cuts into the step 11e₁ to a predetermined depth, which is greater than a bottom surface of the step 11e₁ but does not reach the back surface 11b, with the chuck table 4 kept in a stationary state. FIG. 5A is an enlarged cross-sectional view of the outer peripheral portion 11c of the workpiece 11, and illustrates the second cut in step S20. By rotating the chuck table 4 at least one turn after the second cut in step S20, a step 11e₂ is formed outside the step 11e₁ (second cutting step S30).

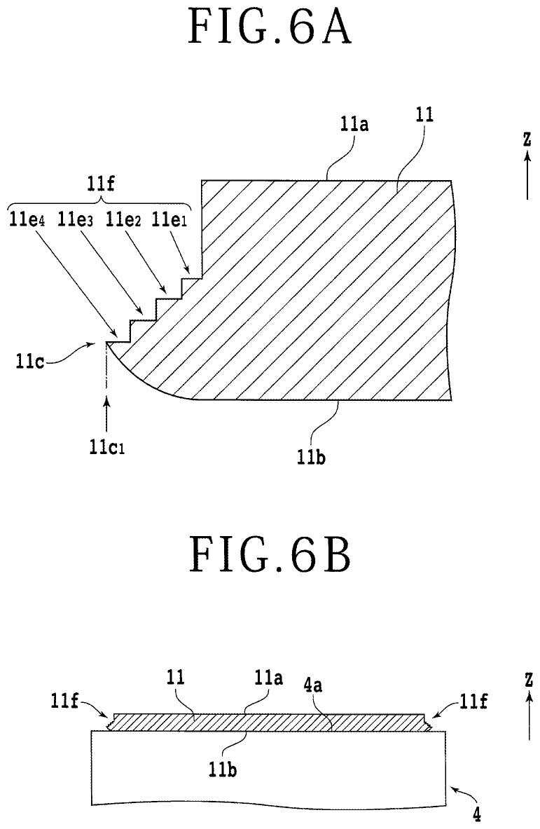

FIG. 5B is an enlarged cross-sectional view of the outer peripheral portion 11c obtained after the second cutting step S30. As a determination of “NO” is made in S40 after the second cutting step S30, the cutting blade 12 is moved to an outer side of the holding surface 4a by the minute distance (second moving step S50). In this embodiment, the cut in step S20, the cutting step S30, and the moving step S50 are repeated in this order. As a consequence, a stepped oblique region 11f is formed on the outer peripheral portion 11c, with a thickness increasing from an outermost peripheral edge 11c₁ (see FIG. 6A) of the workpiece 11 toward an inner side in a radial direction of the workpiece 11.

FIG. 6A is an enlarged cross-sectional view of the outer peripheral portion 11c of the workpiece 11 obtained after the edge trimming. FIG. 6B is a partially cross-sectional view of the workpiece 11 in its entirety and a portion of the chuck table 4, and illustrates the workpiece 11 obtained after the edge trimming of FIG. 6A. FIG. 7 is a flow diagram illustrating the edge trimming method according to the first embodiment of the present invention. The oblique region 11f in this embodiment has steps 11e₃ and 11e₄ in addition to the above-described steps 11e₁ and 11e₂, and is thus formed of the four steps 11e₁, 11e₂, 11e₃, and 11e₄ in total, but the number of these steps are not limited to four. The oblique region 11f has at least two, desirably three or more steps.

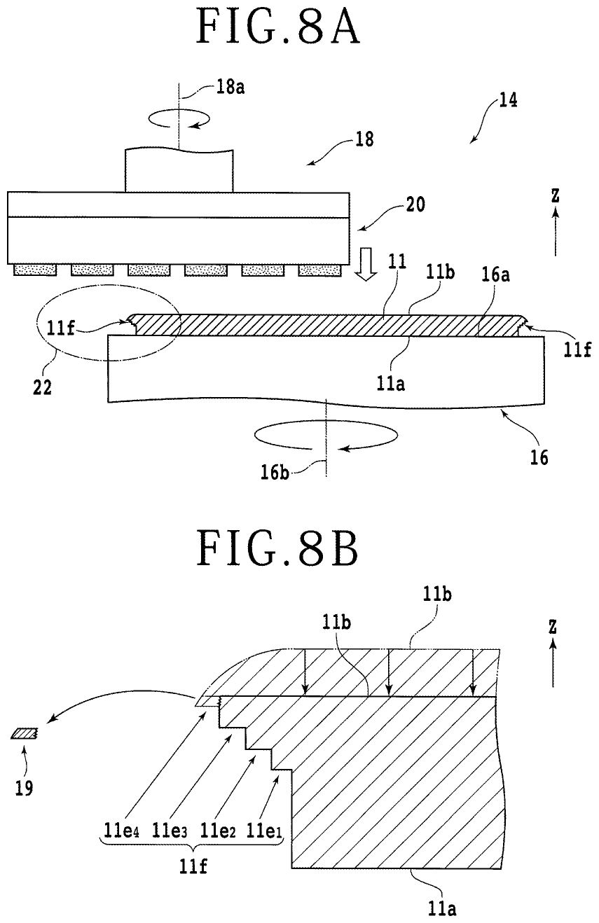

After the formation of the oblique region 11f, the workpiece 11 is ground at the back surface 11b with use of a grinding apparatus 14 (see FIG. 8A). The grinding apparatus 14 has a disc-shaped chuck table 16. The chuck table 16 has a holding surface 16a on which the workpiece 11 is held under suction at the front surface 11a. To a lower portion of the chuck table 16, an output shaft (not illustrated) of a third rotary drive source such as a servo motor is connected. When the third rotary drive source is operated, the chuck table 16 rotates about its axis 16b of rotation.

Above the holding surface 16a, a grinding unit 18 is disposed. The grinding unit 18 has a cylindrical spindle, which extends in parallel to the Z-axis direction and also functions as an axis 18a of rotation. On a lower end portion of the spindle, an annular grinding wheel 20 is mounted via a wheel mount. When grinding the workpiece 11 at the back surface 11b, a resin-made protective tape (not illustrated) is first bonded to the side of the front surface 11a to reduce damage to the devices 15. The workpiece 11 is then held at the front surface 11a under suction on the holding surface 16a via the protective tape.

With the chuck table 16 and the grinding wheel 20 kept rotating in a predetermined direction, downward grinding feed of the grinding unit 18 is next performed. As the workpiece 11 is progressively ground at the back surface 11b, the workpiece 11 becomes gradually thinner. FIG. 8A is a view illustrating how the workpiece 11 is ground at the back surface 11b after the formation of the oblique region 11f by the edge trimming method of FIG. 7. FIG. 8B is an enlarged cross-sectional view of a region 22 surrounded by an ellipse in FIG. 8A. As the stepped oblique region 11f has been formed on the outer peripheral portion 11c in this embodiment, an off-cut itself is rarely generated even when the workpiece 11 is ground at the back surface 11b. If the workpiece 11 is thinned to such an extent that a back surface 11b is formed at a lower position as indicated by arrows in FIG. 8B, however, chipping may occur at the outer peripheral portion 11c on the side of the back surface 11b due to an impact or the like of the grinding, and this chipping may result in an off-cut 19.

In this embodiment, however, the stepped oblique region 11f has been formed. Even if the off-cut 19 is generated, the off-cut 19 can be reduced in volume and arcuate length compared with an arcuate off-cut 19 that would be generated if a workpiece 11 with only one step formed by the conventional edge trimming method is ground at a back surface 11b thereof. Even if the off-cut 19 is generated, there is hence a high possibility of enabling collecting of the off-cut 19 by a grinding debris collecting system (not illustrated) generally arranged in the grinding apparatus 14, thereby enabling reduction of a frequency at which a worker collects off-cuts 19 by hand.

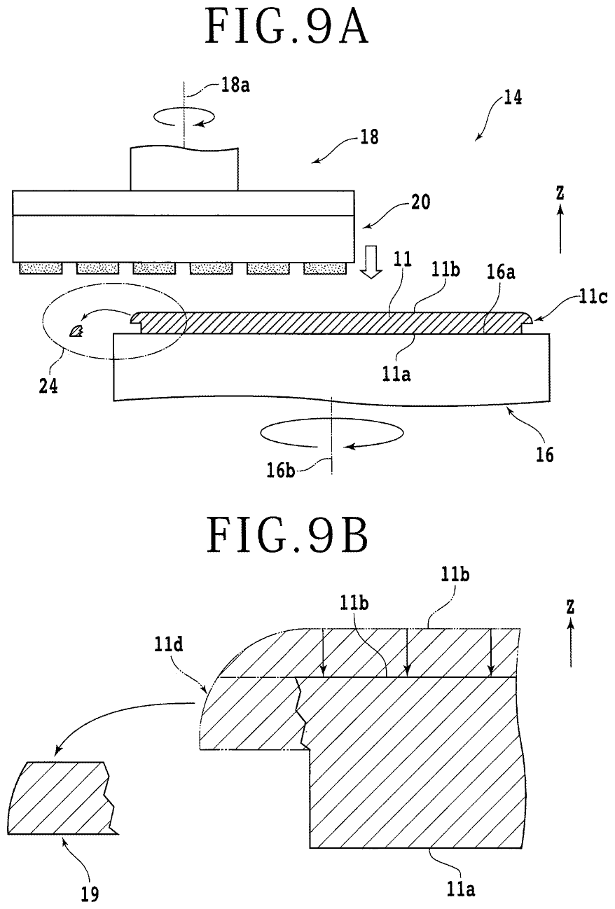

FIG. 9A is a view illustrating how a workpiece 11 that has only one step formed by an edge trimming method according to the comparative example of the first embodiment is ground at a back surface 11b thereof, and FIG. 9B is an enlarged cross-sectional view of a region 24 surrounded by an ellipse in FIG. 9A. If the workpiece 11 with only one step formed on an outer peripheral portion 11c thereof is ground at the back surface 11b, a crack is generated in the step as illustrated in FIG. 9B, so that an off-cut 19 is likely to be generated. Moreover, the off-cut 19 so generated is greater in volume compared with the off-cut 19 in the first embodiment, and therefore the worker needs to collect the off-cut 19 by hand every time the off-cut 19 is generated.

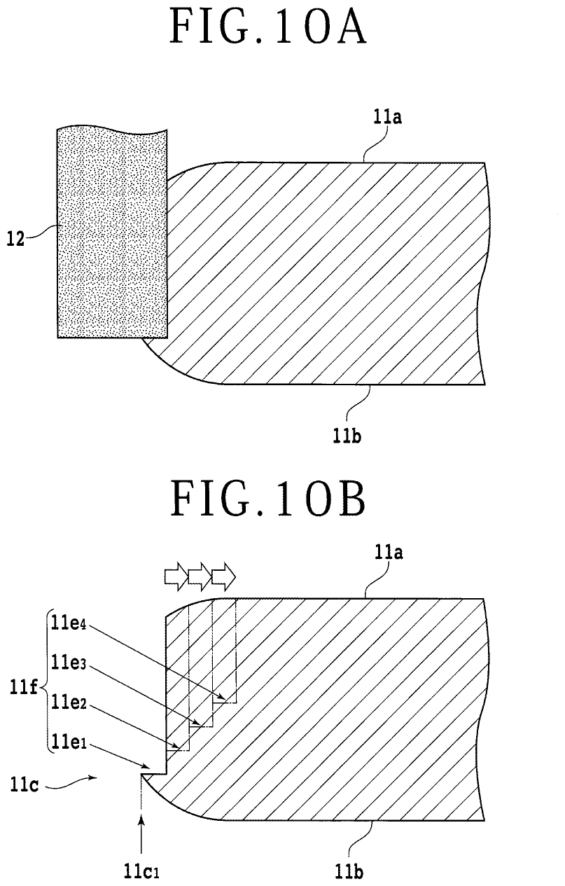

A description will next be made with regard to the modification of the first embodiment. FIG. 10A is an enlarged cross-sectional view of an outer peripheral portion 11c of a workpiece 11, and illustrates a first cut in step in the edge trimming method according to the modification of the first embodiment of the present invention, and FIG. 10B is an enlarged cross-sectional view of the outer peripheral portion 11c of FIG. 10A, and illustrates an order in which a plurality of steps 11e₁ to 11e₄ are formed in the edge trimming method of FIG. 10A. In FIG. 10B, a plurality of arrows indicate the directions and amounts of movements of the cutting blade 12 in a moving step S50. In the first embodiment, the steps 11e₁ to 11e₄ are formed one after another on the outer peripheral portion 11c from an inner side toward the outermost peripheral edge 11c₁ (see FIG. 6A) of the front surface 11a (in other words, in an outward direction). In this modification, on the other hand, the steps 11e₁ to 11e₄ are formed one after another on the outer peripheral portion 11c from an outermost peripheral edge 11c₁ toward an inner side of a front surface 11a (in other words, in an inward direction). As in the first embodiment, a stepped oblique region 11f can be also formed on the outer peripheral portion 11c in this modification, with a thickness increasing from the outermost peripheral edge 11c₁ toward the inner side in the radial direction of the workpiece 11.

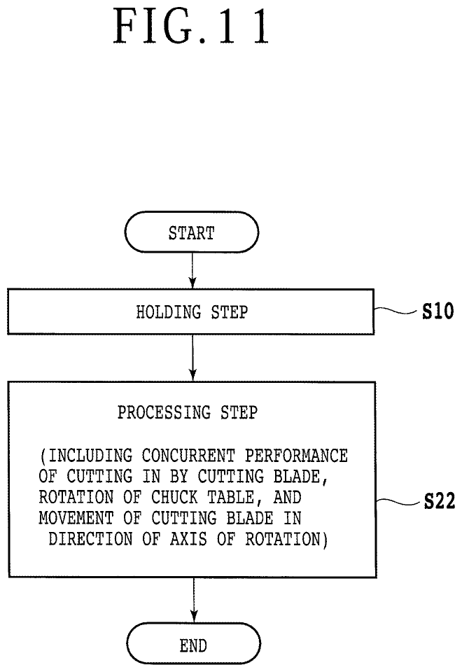

A description will next be made with regard to the second embodiment. FIG. 11 is a flow diagram of an edge trimming method according to the second embodiment. To facilitate understanding of the edge trimming method according to the second embodiment, FIGS. 2A, 3A, 4A, 8A, and 10B will also be referred to as needed. In the second embodiment, after a holding step S10, a stepped oblique region 11f is formed on an outer peripheral portion 11c, with a thickness increasing from an outermost peripheral edge 11c₁ toward an inner side in a radial direction of a workpiece 11 (processing step S22). It is however to be noted that the processing step S22 concurrently performs causing the cutting blade 12 to cut into the outer peripheral portion 11c of the workpiece 11, rotating the chuck table 4, and moving the cutting blade 12 in the direction of the axis 10a of rotation of the spindle 10.

In the cutting in by the cutting blade 12 in the processing step S22, the rotating cutting blade 12 and the chuck table 4 are relatively moved through a downward movement of the cutting unit 6 by the Z-axis moving mechanism. In other words, the cutting blade 12 cuts into the outer peripheral portion 11c by what is generally called chopper cutting. Here, the cut in depth is gradually increased with time. Further, if the cutting blade 12 is to be moved in the processing step S22, the cutting unit 6 is gradually moved with time along the Y-axis direction from an inner side to an outer side of the holding surface 4a with use of the Y-axis moving mechanism.

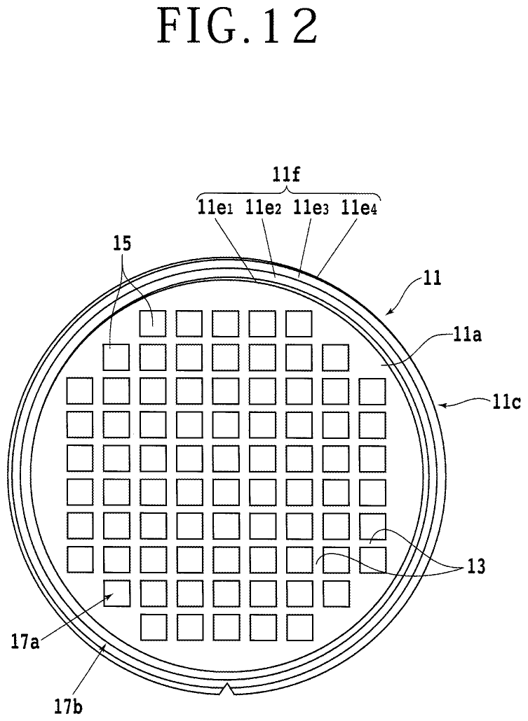

As a consequence, the outer peripheral portion 11c is processed such that bottom surfaces of plurality steps 11e₁, 11e₂, 11e₃, and 11e₄ extend helically when the oblique region 11f is viewed in plan (see FIG. 12). FIG. 12 is a top plan view of the workpiece 11 obtained after the processing. For the movement of the cutting blade 12 in the processing step S22, the cutting blade 12 that has cut into an outside of the outer surplus region 17b may be moved from the outside to an inner side of the outer surplus region 17b as in the above-described modification. In this case, however, the cut in depth is gradually decreased with time.

In the second embodiment, an off-cut 19 itself is also rarely generated as in the first embodiment even if the workpiece 11 is ground at the back surface 11b. Even if the off-cut 19 is generated, the off-cut 19 can be reduced in volume and arcuate length compared with the arcuate off-cut 19 that will be generated if the workpiece 11 with only one step formed by the conventional edge trimming method is ground at the back surface 11b thereof. Even if the off-cut 19 is generated, there is hence a high possibility of enabling collecting of the off-cut 19 by the grinding debris collecting system (not illustrated) generally arranged in the grinding apparatus 14, thereby enabling a reduction in the frequency at which the worker collects off-cuts 19 by hand.

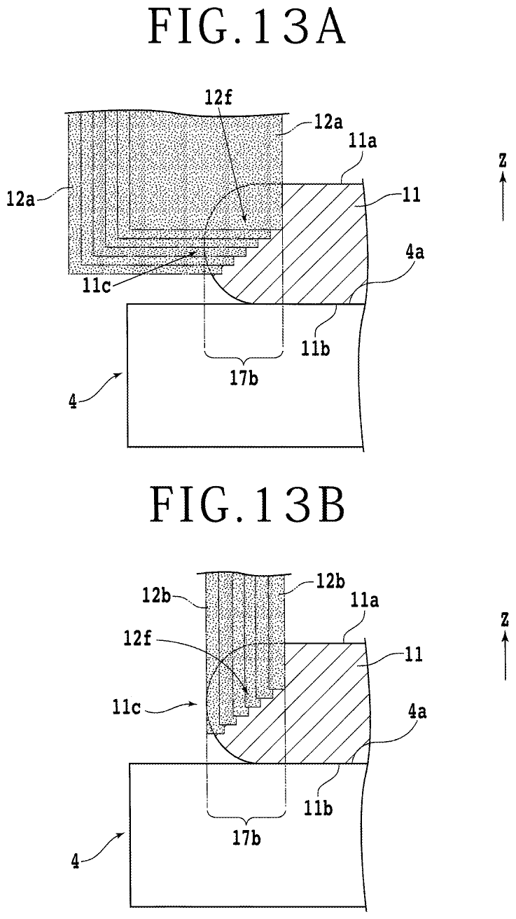

A description will next be made with regard to the third embodiment. FIG. 13A is an enlarged, partially cross-sectional view of an outer peripheral portion 11c of a workpiece 11 and the portion of the chuck table 4, and illustrates an edge trimming method according to the third embodiment, in which a cutting blade 12a having a blade thickness greater than the width of an outer peripheral surplus region 17b is used. With the use of the cutting blade 12a, all of the first and second embodiments and the above-described modification can also be practiced. The greater the blade thickness, the more resistant the cutting blade is to deformation even if stress is applied in the direction of the blade thickness. The cutting blade 12a is thus particularly suited for the formation of the helical oblique region 11f described in FIG. 2.

A description will next be made with regard to the fourth embodiment. FIG. 13B is an enlarged, partially cross-sectional view of an outer peripheral portion 11c of a workpiece 11 and the portion of the chuck table 4, and illustrates an edge trimming method according to the fourth embodiment, in which a cutting blade 12b having a blade thickness smaller than the width of an outer peripheral surplus region 17b is used. With the use of the cutting blade 12b, all of the first and second embodiments and the above-described modification can also be practiced. Especially, when the cutting blade 12b is used, the cutting blade 12b cuts the workpiece 11 at its entire surface on a side of its outer periphery, and thus, there is an advantage that uneven wear rarely occurs compared with the cutting blade 12a of the great blade thickness.

In addition, the configurations, the methods, and the like according to the above-described embodiments can be practiced with changes or modifications as needed to such an extent as not departing from the scope of the object of the present invention. The present invention is not limited to the details of the above-described preferred embodiments. The scope of the invention is defined by the appended claims and all changes and modifications as fall within the equivalence of the scope of the claims are therefore to be embraced by the invention.

What is claimed is:

1. An edge trimming method for cutting an outer peripheral portion of a workpiece having a chamfered part on the outer peripheral portion, comprising:
a holding step of holding the workpiece on a holding surface of a chuck table;
a cut in step of, after the holding step, relatively moving a rotating cutting blade and the chuck table to cause the cutting blade to cut into the outer peripheral portion of the workpiece;
a cutting step of, after the cut in step, rotating the chuck table and causing the outer peripheral portion of the workpiece to be cut, to form an annular step; and
a moving step of, after the cutting step, moving the cutting blade in a direction of an axis of rotation of the cutting blade to form another annular step adjacent to the first-mentioned annular step,
wherein the cut in step, the cutting step, and the moving step are repeated in this order, and a stepped oblique region is formed on the outer peripheral portion, with a thickness increasing from an outermost peripheral edge toward an inner side of the workpiece.

2. An edge trimming method for cutting an outer peripheral portion of a workpiece having a chamfered part on the outer peripheral portion, comprising:
a holding step of holding the workpiece on a holding surface of a chuck table; and
a processing step of, after the holding step, concurrently performing relatively moving a rotating cutting blade and the chuck table to cause the cutting blade to cut into the outer peripheral portion of the workpiece, rotating the chuck table, and moving the cutting blade in a direction of an axis of rotation of the cutting blade,
wherein, in the processing step, a stepped oblique region is formed on the outer peripheral portion, with a thickness increasing from an outermost peripheral edge toward an inner side of the workpiece and also with a bottom surface helically formed over a plurality of steps when the oblique region is viewed in plan.
